(19) United States
(12) Patent Application Publication
(10) Pub. No.: US 2013/0247964 A1
(43) Pub. Date: Sep. 26, 2013

(54) PHOTOELECTRIC CONVERSION MODULE

(71) Applicants: Yosuke Inomata, Ise-shi (JP); Masahiro Yokota, Sakura-shi (JP); Shintaro Mitsuno, Omihachiman-shi (JP); Norihiko Matsushima, Yasu-shi (JP); Hisao Arimune, Omihachiman-shi (JP)

(72) Inventors: Yosuke Inomata, Ise-shi (JP); Masahiro Yokota, Sakura-shi (JP); Shintaro Mitsuno, Omihachiman-shi (JP); Norihiko Matsushima, Yasu-shi (JP); Hisao Arimune, Omihachiman-shi (JP)

(73) Assignee: KYOCERA CORPORATION, Kyoto-shi, Kyoto (JP)

(21) Appl. No.: 13/990,720

(22) PCT Filed: Nov. 29, 2011
(86) PCT No.: PCT/JP2011/077470

§ 371 Date: May 30, 2013

(30) Foreign Application Priority Data
Nov. 30, 2010 (JP) 2010-266588

(51) Int. Cl. H01L 31/048

(52) U.S. Cl. CPC H01L 31/0485
USPC 136/251

(57) ABSTRACT

A photoelectric conversion module is disclosed. The photoelectric conversion module includes a photoelectric conversion panel and a moisture barrier plate. The photoelectric conversion panel includes first and second surfaces, a photoelectric converter between the first and second surfaces, and a conductive lead. An opening is located on the first surface. The moisture barrier plate is located on the second surface and includes first and second principal surfaces, and a through-hole extending from the first principal surface to the second principal surface. The moisture barrier plate covers the one principal surface. The through-hole does not overlap the opening. A filling member is located in a gap between the first surface and the first principal surface. The conductive lead goes through a part of the filling member, and has an end electrically coupled to the photoelectric converter and the other end coming out through the opening to the exterior.

### TECHNICAL FIELD

The present invention relates to a photoelectric conversion module.

### BACKGROUND ART

In recent years, solar power generation in which light energy is converted into electrical energy has attracted attention.

At a photoelectric conversion module used for such solar power generation, electricity obtained from a photoelectric converter at a photoelectric conversion panel provided at the photoelectric conversion module is extracted therefrom by conductive leads such as wire leads or the like. Such conductive leads are guided into the interior of a terminal box arranged at the non-light-receiving surface of the photoelectric conversion panel. At Japanese Patent Application Publication Kokai No. 2003-282915 and Japanese Patent Application Publication Kokai No. 2010-118394, electricity generated at a photoelectric conversion module is connected to external circuitry or the like by way of a terminal box.

### SUMMARY OF INVENTION

At the aforementioned photoelectric conversion module, through-hole(s) and the like are formed and an opening portion is provided for routing conductive leads through members which are present at the non-light-receiving side of the photoelectric conversion panel so that conductive leads (output wire leads) connected to photoelectric converter(s) can be guided into terminal box(es). Photoelectric conversion modules installed outdoors over long periods of time such as, for example, ten years or more have experienced deterioration of components at photoelectric converters and the like within photoelectric conversion panels due to entry of moisture and/or water from the foregoing opening portion. There have been cases where this has caused occurrence of lowered output at the photoelectric conversion module.

It is one object of the present invention to provide a photoelectric conversion module that has high reliability and that reduces entry of moisture/water into the interior of a photoelectric conversion panel.

A photoelectric conversion module according to an embodiment of the present invention comprises a photoelectric conversion panel. This photoelectric conversion panel includes a light-receiving surface, a non-light-receiving surface corresponding to a back surface relative to the light-receiving surface, a photoelectric converter located between the light-receiving surface and the non-light-receiving surface, a conductive lead electrically connected to the photoelectric converter, and an opening portion which is open at the non-light-receiving surface and through which the conductive lead is guided to the exterior. Furthermore, this photoelectric conversion module comprises a moisture barrier plate that has a one principal surface, an other principal surface corresponding to a back surface relative to the one principal surface, and a through-hole extending between the one principal surface and the other principal surface, and that is arranged at the non-light-receiving side so as to cause the opening portion to be covered by the one principal surface. In the present embodiment, this moisture barrier plate is arranged such that, as seen in plan view, the through-hole does not overlap the opening portion. Moreover, in the present embodiment, the conductive lead is arranged so as to create a gap between the non-light-receiving surface and the one principal surface at a location between the non-light-receiving surface and the one principal surface and is guided to the exterior from the through-hole. In addition, in the present embodiment, filling member is arranged in the gap.

A photoelectric conversion module according to an embodiment of the present invention can reduce the amount of moisture/water that enters from the opening portion and is directed toward photoelectric converter(s). This can improve reliability of the photoelectric conversion module.

### BRIEF DESCRIPTION OF DRAWINGS

FIG. 1 is a perspective view of a photoelectric conversion module according to an embodiment as seen from the non-light-receiving side thereof.

FIG. 2 is a partial enlarged sectional view of a photoelectric conversion panel which is a portion of a photoelectric conversion module according to an embodiment.

FIG. 3 is a perspective view showing a portion of a photoelectric conversion panel at a photoelectric conversion module according to an embodiment.

FIG. 4 is a sectional view at the location indicated by alternating long and short chain line A-A in FIG. 1.

FIG. 5 is a sectional view showing in schematic fashion a region in the vicinity of a terminal box at a photoelectric conversion module according to one embodiment.

FIG. 6 is a sectional view showing in schematic fashion a region in the vicinity of a terminal box at a photoelectric conversion module according to another embodiment.

FIG. 7 is a partial sectional view showing a variation on the photoelectric conversion module and the terminal box at the photoelectric conversion module.

FIG. 8 is a partial sectional view showing a variation on the photoelectric conversion module and the terminal box at the photoelectric conversion module.

FIG. 9 is a partial sectional view showing a variation on the photoelectric conversion module and the terminal box at the photoelectric conversion module.

FIG. 10 is a partial sectional view showing a variation on the photoelectric conversion module and the terminal box at the photoelectric conversion module.

FIG. 11 is a schematic exploded view showing in schematic fashion a portion of a photoelectric conversion module according to another embodiment.

FIG. 12 is an enlarged sectional view showing in schematic fashion a region in the vicinity of the terminal box in FIG. 11.

FIG. 13 is a plan view showing in schematic fashion a light-receiving surface of a photoelectric converter which is a portion of a photoelectric conversion module.

FIG. 14 is a plan view showing in schematic fashion a light-receiving surface at a photoelectric conversion module.

FIG. 15 is a sectional view showing in schematic fashion a region in the vicinity of a terminal box at a photoelectric conversion module according to another embodiment.

### EMBODIMENTS FOR CARRYING OUT THE INVENTION

One of embodiments of photoelectric conversion modules according to the present invention will be described while referring to the drawings. In the following embodiments, note that a thin-film-type photoelectric conversion module and a crystalline-type photoelectric conversion module are respectively described.

### <Thin-Film-Type Photoelectric Conversion Module>

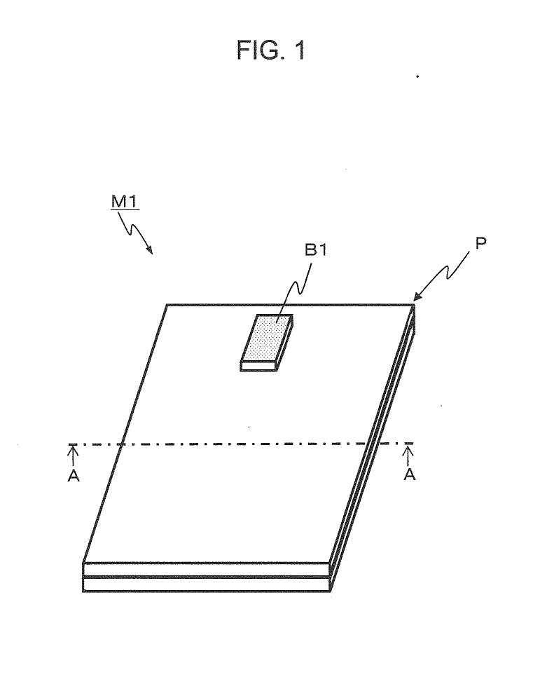

As shown in FIG. 1, a photoelectric conversion module M1 includes a photoelectric conversion panel PA and a terminal box B1 arranged at a non-light-receiving surface of the photoelectric conversion panel.

### (Photoelectric Conversion Panel)

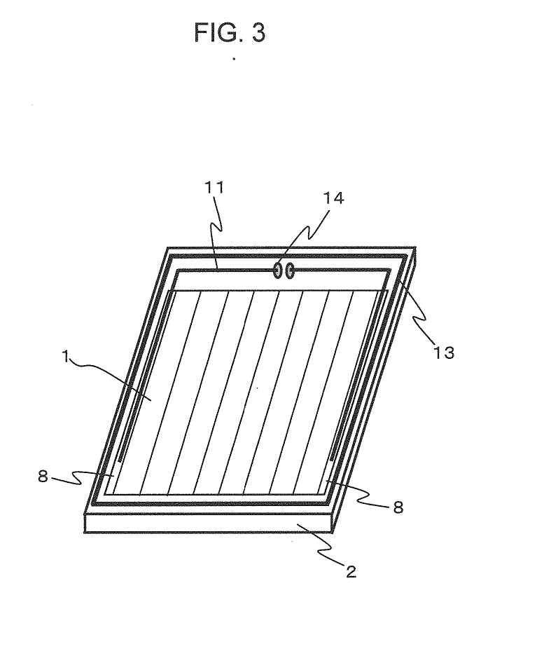

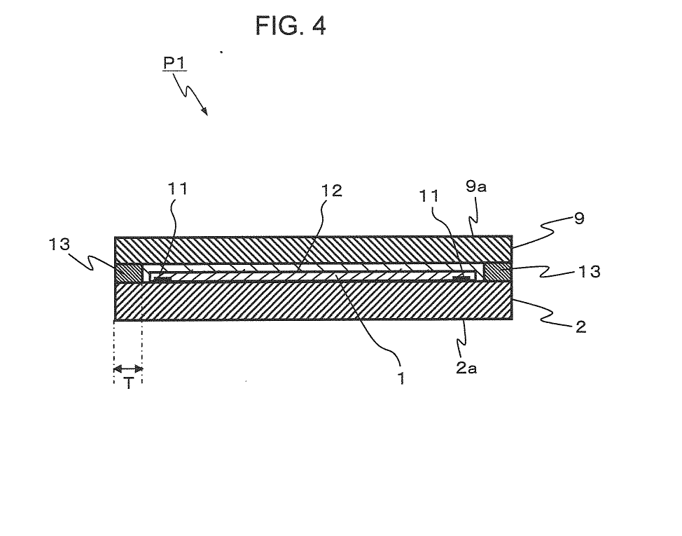

As shown in FIG. 3 and FIG. 4, the photoelectric conversion panel PA includes a photoelectric converter 1, a first substrate 2, a second substrate 9, one or more conductive leads 11, a first sealing member 12, and a second sealing member 13. In FIG. 3, the second substrate 9 is omitted so as to facilitate description of the internal structure of photoelectric conversion panel PA.

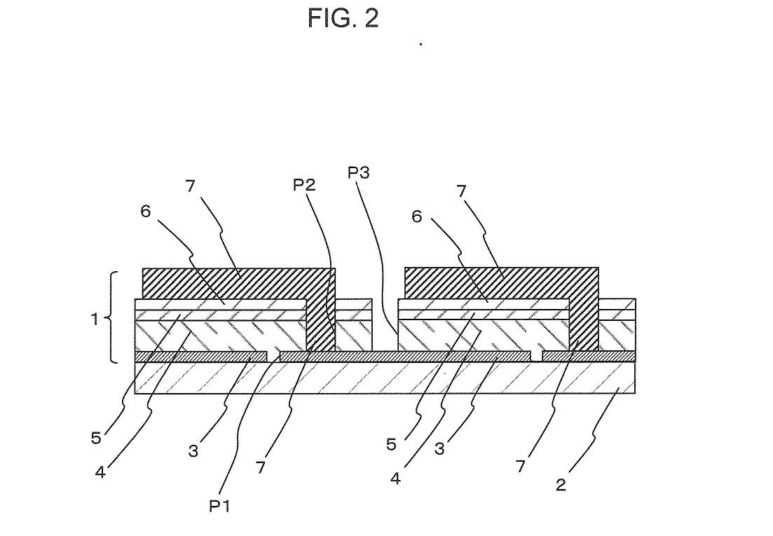

As shown in FIG. 2, the photoelectric converter 1 is arranged on one principal surface of first substrate 2, absorbs light incident thereon from the exterior, and has functionality for converting light into electricity. As shown in FIG. 2, this photoelectric converter 1 is formed by a back electrode 3, a semiconductor layer 4, a buffer layer 5, a translucent electrically conductive layer 6, and a current-collecting electrode 7, which are sequentially stacked on the one principal surface of first substrate 2.

The first substrate 2 has functionality for supporting the photoelectric converter 1. As material for this first substrate 2, soda-lime glass (soda-lime glass) having a thickness of an order of 1 mm to 3 mm; heat-resistant plastic such as polyimide resin or the like; and metal foil such as stainless steel, titanium or other such metal foil having a thickness of the order of 100 μm to 200 μm, the surface of which is covered with an oxide film or other such insulating film, are cited as examples. Furthermore, first substrate 2 is planar and has rectangular, circular, or other such shape.

Back electrode 3 has functionality for carrying out conduction of charge produced as a result of absorption of light by semiconductor layer 4, described below. As material for this back electrode 3, metals such as molybdenum, titanium, tantalum or the like; structures in which such metals are arranged in stacked layers; and the like are cited as examples. Furthermore, thickness of back electrode 3 may be on the order of 0.3 μm to 2 μm.

Semiconductor layer 4 is capable of functioning as a light absorbing layer, and is of p-type semiconductor conduction type. As material for this semiconductor layer 4, copper indium diselenide (CuInSe₂), copper indium gallium diselenide (CuInGaSe₂), copper indium gallium selenium sulfide (CuInGaSeS), copper indium gallium disulfide (CuInGaS₂), or chalcopyritic compound such as copper indium gallium diselenide (CuInGaSe₂) or the like including a surface layer of copper indium gallium selenium sulfide (CuInGaSeS) thin film are cited as examples. Furthermore, a thickness on the order of 1 μm to 3 μm is sufficient for semiconductor layer 4.

Buffer layer 5 is disposed on the semiconductor layer 4, and is of different conduction type from semiconductor layer 4. That is, if semiconductor layer 4 is p-type, then buffer layer 5 is of n-type. Thus, a pn junction is formed at the interface between semiconductor layer 4 and buffer layer 5. As buffer layer 5, CdS, ZnS, ZnO, In₂Se₃, In(OH, S), (Zn, In)(Se, OH), (Zn, Mg)O, and the like are cited as examples, the chemical bath deposition (CBD) or the like being employed for formation thereof. Here, In(OH, S) refers to a compound composed primarily of In, OH, and S. Furthermore, (Zn, In)(Se, OH) refers to a compound composed primarily of Zn (zinc), In, Se, and OH. Furthermore, (Zn, Mg)O refers to a compound composed primarily of Zn, Mg (magnesium), and O (oxygen).

In the present embodiment, if translucent electrically conductive layer 6 contains indium oxide, buffer layer 5 may be in a form containing indium. This will make it possible to reduce variation in electrical conductivity occurring due to interdiffusion of elements between buffer layer 5 and translucent electrically conductive layer 6. Moreover, if a chalcopyritic material that contains indium is employed as semiconductor layer 4, this will permit reduction in variation in electrical conductivity and carrier density due to interdiffusion of elements among the respective layers comprising semiconductor layer 4, buffer layer 5, and translucent electrically conductive layer 6.

Furthermore, buffer layer 5 may contain Group III-VI compound(s) as main component(s). This will make it possible to improve moisture resistance of photoelectric converter 1. Note that Group III-VI compound refers to a compound formed by a Group III-B element and a Group VI-B element. Furthermore, what is meant by a buffer layer 5 that contains Group III-VI compound(s) as main component(s) is that not less than 50 mol % of the compounds contained in the buffer layer 5 are Group III-VI compound(s). In such case, Group III-VI compound(s) may be present therein in an amount that is not less than 80 mol %. Moreover, the element Zn may be present in an amount that is not more than 50 atomic % of the metal elements making up buffer layer 5. This will make it possible to improve moisture resistance of photoelectric conversion panel PA. In such case, the element Zn may be present therein in an amount that is not more than 20 atomic %.

Furthermore, thickness of buffer layer 5 may be 10 nm to 200 nm. This will make it possible to reduce excessive increase in series resistance. Buffer layer 5 may in addition be optically transmissive with respect to the range of wavelengths of light that is absorbed by semiconductor layer 4. This will make it possible to increase efficiency of absorption at semiconductor layer 4. Furthermore, resistivity of buffer layer 5 may be not less than 1 Ω-cm. This will permit reduction in leakage current.

Translucent electrically conductive layer 6 is provided on buffer layer 5, and has functionality for carrying out conduction of charge produced at pn junction region(s) as a result of absorption of light by semiconductor layer 4. As material for this translucent electrically conductive layer 6, for example, compounds such as zinc oxide (ZnO), indium oxide (ITO) which includes aluminum and tin, tin oxide (SnO₂) or zinc oxide which includes boron, gallium, indium, fluorine, and/or the like, are cited as examples. Specifically, zinc oxide and indium tin oxide which includes tin have better optical transmittance and resistance as compared with other materials. Furthermore, thickness of translucent electrically conductive layer 6 is on the order of 0.05 μm to 2 μm.

Current-collecting electrode 7 is provided on translucent electrically conductive layer 6, and has functionality for collecting charge from translucent electrically conductive layer 6. If current-collecting electrode 7 is formed from material(s) of lower resistance than translucent electrically conductive layer 6, this will make it possible for charge to be collected efficiently. When the translucent electrically conductive layer 6 is formed from the aforementioned material(s), current-collecting electrode 7 may be configured to be metal material such as silver, copper, or the like. Furthermore, such current-collecting electrode 7 may be formed, for example, by screen printing or the like.

At the photoelectric converter 1, isolation trenches P1 thru P3 are provided at respective layers formed on a single first substrate 2. This makes it possible for a plurality of photoelectric conversion units formed in the photoelectric converter 1 to be made to an embodiment in which the units are electrically connected in series through use of a portion of current-collecting electrode(s) 7. In such an embodiment, integration of photoelectric conversion units will permit improvement in output voltage. Moreover, as shown in FIG. 3, respectively provided at either end portion of photoelectric converter 1 are output-extracting portions 8. For example, one of the output-extracting portions 8 may correspond to a back electrode 3 located at one end of photoelectric converter 1. Furthermore, the other of the output-extracting portions 8 may correspond to region(s) located at at least one of current-collecting electrode 7 and translucent electrically conductive layer 6 located at the other end of photoelectric converter 1. At such time, one of the output-extracting portions 8 would be a cathode, and the other of the output-extracting portions 8 would be an anode. In addition, conductive leads 11 would be electrically connected to this pair of output-extracting portions 8. That is, the photoelectric converter 1 is electrically connected to the conductive leads. Note that when output-extracting portion 8 is to be provided at back electrode 3, a region at which semiconductor layer 4, buffer layer 5, and the like are not formed may itself be used as output-extracting portion 8. This will make it possible to eliminate the step for forming output-extracting portion 8. Furthermore, speaking of the output-extracting portion 8, when output-extracting portion 8 is provided at translucent electrically conductive layer 6, translucent electrically conductive layer 6 itself or current-collecting electrode 7 itself may be used as output-extracting portion 8. Furthermore, for connection between the output-extracting portion(s) 8 and the conductive leads 11, electrically conductive adhesive which contains electrically conductive particles such as silver, and the like, may, for example, be used. This will make it possible to reduce electrical resistance while maintaining adhesive strength. Note that the output-extracting portion(s) 8 may be formed such that a stacked region including semiconductor layer 4, buffer layer 5, and translucent electrically conductive layer 6 is formed on the first substrate 2; a portion of the stacked region is thereafter removed; and current-collecting electrode(s) 7 are made to extend to portion(s) of the removed portion.

An exemplary method of manufacturing photoelectric converter 1 will next be described.

Back electrode 3 is first be formed with using sputtering method by depositing a metal such as molybdenum, and the like, on approximately the entire surface, except for a region on the order of 3 mm to 10 mm inward from the periphery, of cleaned first substrate 2 such as soda-lime glass. Patterning of back electrode 3 is then carried out by using a YAG laser or the like to irradiate desired location(s) at back electrode 3 to form the isolation trench P1. Sputtering method, vapor deposition method, printing method, or the like may thereafter be used to form semiconductor layer 4 on the patterned back electrode 3. CBD method or the like may then be used to form buffer layer 5 on the semiconductor layer 4. Sputtering method, metal-organic chemical vapor deposition (MOCVD) method, or the like may then be used to form translucent electrically conductive layer 6 on the buffer layer 5. Mechanical scribing or the like may then be used to form the isolation trench P2 and the isolation trench P3, and patterning of the semiconductor layer 4, the buffer layer 5, and the translucent electrically conductive layer 6 may be carried out. Screen printing method or the like may then be employed to apply metal paste on the translucent electrically conductive layer 6, this thereafter being fired to form current-collecting electrode(s) 7.

Second substrate 9 has functionality for protecting photoelectric converter 1 from the external environment. Furthermore, as shown in FIG. 4, because a photoelectric conversion panel PA is such that light is primarily incident thereon from the second substrate 9 side thereof, the second substrate 9 includes light-receiving surface 9a. Conversely, at photoelectric conversion panel PA, the other principal surface, which corresponds to the back surface relative to the one principal surface of first substrate 2, is non-light-receiving surface 2a. Note that the “non-light-receiving surface” is intended to indicate a surface on which the light which primarily contributes to photoelectric conversion is not incident, and is not intended to mean that no light whatsoever can be incident thereon. Furthermore, for the shape and material of the second substrate 9, besides tempered super water glass, similar materials to the first substrate 2 may also be employed.

The conductive leads 11 have functionality for guiding electricity obtained from output-extracting portion 8 to the exterior. As such conductive leads 11, metal foil such as copper (Cu) having thickness on the order of 0.1 mm to 0.5 mm and width on the order of 1 mm to 7 mm is cited as an example. Furthermore. The surface of such metal foil may be coated with tin, nickel, solder, or the like. This will permit satisfactory electrical connection to the output-extracting portion 8.

Furthermore, an opening portion 14, which is open in the direction of non-light-receiving surface 2a, is formed at first substrate 2. Such opening portion 14 is a hole which is formed from the one principal surface of the first substrate 2 to the other principal surface thereof (non-light-receiving surface 2a). With this, the conductive leads 11 can pass through the opening portion 14 and be guided to the exterior. This opening portion 14 may be provided in advance prior to formation of photoelectric converter 1 or may be provided following formation of photoelectric converter 1. In a case where the material of the first substrate 2 is glass or plastic, or metal such as stainless steel, opening portion 14 may be formed by machining method using a drill or by laser processing method using a YAG (yttrium-aluminum-garnet) laser or the like.

First sealing member 12, which has functionality for protecting photoelectric converter 1 while adhering first substrate 2 and second substrate 9, is arranged so as to cover photoelectric converter 1. Furthermore, the first sealing member 12 is translucent. As material for such first sealing member 12, a resin having copolymerized ethylene-vinyl acetate copolymer (hereinafter “EVA”) as main component is cited as an example. In such case, to promote crosslinking of resin, the EVA may include crosslinking agent such as triallyl isocyanurate.

The second sealing member 13 is arranged at periphery portion of first substrate 2 and second substrate 9. While the second sealing member 13 is arranged between the first substrate 2 and the second substrate 9 in the present embodiment, it is also possible for the second sealing member 13 to be arranged so as to cover the outside circumferential faces of the first substrate 2 and the second substrate 9. This second sealing member 13 has functionality for reducing entry of moisture/water and the like into photoelectric converter 1. Such second sealing member 13 may constitute resin which contains desiccant. As such resin, butyl rubber, urethane, polyurethane, and so forth are cited as examples. Furthermore, the desiccant is desiccant that has functionality for physically or chemically adsorbing or absorbing moisture/water which has entered thereinto. As such desiccant, anhydrous compounds, clay, zeolite, molecular sieves such as porous glass, silica gel, calcium chloride, magnesium sulfide, calcium oxide, magnesium oxide, and so forth are cited as examples.

Next, an exemplary method for manufacturing photoelectric conversion panel PA will be described. Photoelectric converter 1 may first be formed on the first substrate 2 as described above. Conductive leads 11 may then be attached to output-extracting portion(s) 8 of photoelectric converter 1. The member(s) used to connect the conductive leads 11 and the output-extracting portion 8 may be chosen as appropriate in correspondence to the material(s) used at conductive leads 11 and output-extracting portion 8. For example, when a portion of back electrode 3 which contains molybdenum is used as output-extracting portion 8, solder which contains indium may be used for connection thereof. Or when a portion of translucent electrically conductive layer 6 which comprises ITO is used as output-extracting portion 8, electrically conductive adhesive comprising epoxy resin or the like into which silver or other such filling member has been kneaded may be used for connection thereof. Or when the output-extracting portion 8 is formed from silver or copper, solder which has been provided in advance at conductive leads 11 may be used for connection thereof.

Then, as shown in FIG. 3, the conductive leads 11, which are arranged peripherally about the photoelectric converter 1, is bent appropriately in the direction of opening portion 14, and is guided toward the non-light-receiving-surface 2a side thereof by way of opening portion 14. Then the second sealing member 13 having width T is applied to circumference of the photoelectric converter 1 on the first substrate 2. Then, a sheet-like and on-the-order-of-0.1-mm-to-0.6-mm-thick first sealing member 12 and second substrate 9 are arranged and stacked in this order on the photoelectric converter 1. These laminated bodies are lastly placed in a laminator, where it is, for example, held at 100° C. to 200° C. for on the order of 15 min to 60 min while being pressed under reduced pressure, causing softening and crosslinking of the EVA so that the laminated body becomes an integral structure, to manufacture a photoelectric conversion panel PA. Note that the second sealing member 13 may be applied on the first substrate 2, or a tape-like member which has formed in advance may be placed on the first substrate 2 or the second substrate 9.

Terminal Box

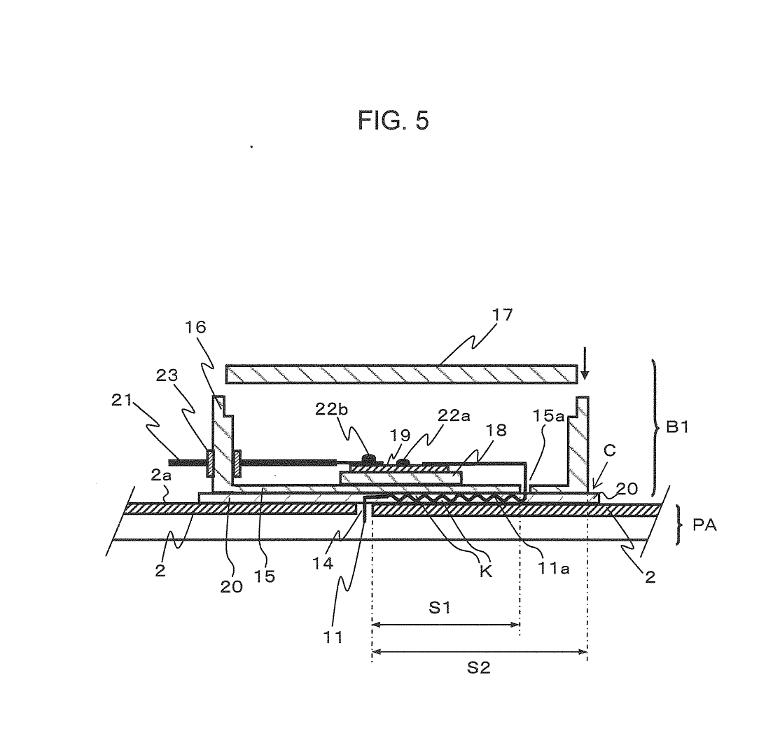

As shown in FIG. 5, a terminal box B1 is attached to the non-light-receiving surface 2a of the photoelectric conversion panel PA. The terminal box B1 is equipped with a moisture barrier plate 15, a frame 16, and a lid member 17.

The moisture barrier plate 15 is arranged such that one principal surface thereof faces the non-light-receiving surface 2a. Furthermore, at the moisture barrier plate 15 of the present embodiment, a stage 18, a terminal 19, and so forth are mounted on the other principal surface, which corresponds to the back surface relative to the one principal surface. The moisture barrier plate 15 is composed of material(s) not readily permeated by moisture/water. That is, the moisture barrier plate 15 is not a member that is not permeated by moisture/water whatsoever. In addition, the moisture barrier plate 15 may have insulating characteristics. This will permit reduction in occurrence of short circuits that may otherwise be caused by contact with the conductive leads 11. Furthermore, because the moisture barrier plate 15 is in compressive contact with conductive leads 11 and non-light-receiving surface 2a, the material(s) may be chosen therefor of sufficient strength to withstand the compressive contact. As such material, a glass-type material which is not readily permeated by moisture/water, which is of comparatively high strength, and which has insulating characteristics is desirable. As another material, a resin having low permeability with respect to moisture/water such as polyethylene may also be used therefor. When such resin is used, a material in which a metal layer intervenes between layers of such resin may be employed. This will permit further reduction in permeation thereof by moisture/water. A material including a metal sheet that has been coated with resin, glass, or the like may also be employed as the moisture barrier plate 15.

Furthermore, the moisture barrier plate 15 is provided with a through-hole 15a which extend from the one principal surface of the moisture barrier plate 15 to the other principal surface thereof. Such through-hole 15a is used to guide the conductive leads 11 to terminal 19 provided on the other principal surface of the moisture barrier plate 15. That is, the conductive leads 11 are guided to the side thereof at which the terminal 19 is present by way of the through-hole 15a.

In addition, at photoelectric conversion module M1, the moisture barrier plate 15 is arranged such that the opening portion 14 is covered by the one principal surface thereof. Thus, in the present embodiment, because the moisture barrier plate 15 is arranged so as to cover opening portion 14, it is possible to reduce the size of the entrance through which moisture/water enters the opening portion 14 as compared with the situation in which the moisture barrier plate 15 is not provided. Such moisture/water tends to enter from joint C between the photoelectric conversion panel PA and a frame member 16 located at the periphery of the moisture barrier plate 15. In the present embodiment, however, because the distance 51 from the joint C to the opening portion 14 can be made large, it is possible to further reduce entry of moisture/water.

Furthermore, the moisture barrier plate 15 is arranged such that, as the moisture barrier plate 15 is seen in plan view, the through-hole 15a does not overlap the opening portion 14. As a result, as the moisture barrier plate 15 is seen in plan view, this causes the distance S2 to exist between the through-hole 15a and the opening portion 14. When such distance S2 is present, moisture/water entering from the through-hole 15a side will not readily reach the opening portion 14. Note that moisture/water entering from the through-hole 15a side is primarily moisture/water that enters from the joint between the lid member 17 and the frame member 16.

Furthermore, as shown in FIG. 5, the conductive leads 11 are arranged between the one principal surface of the moisture barrier plate 15 and the non-light-receiving surface 2a of the photoelectric conversion panel PA. At such time, the conductive leads 11 are arranged such that a gap K is created between the non-light-receiving surface 2a and the moisture barrier plate 15, filling member 20 being arranged within this gap K.

The filling member 20 is composed of material which permits the moisture barrier plate 15 to adhere to the non-light-receiving surface 2a of the photoelectric conversion panel PA. As such material, polyolefinic resins such as butyl rubber (polyisobutene-isoprene), polyethylene, polypropylene, polybutene, polyisobutylene, and the like, are cited as examples. Furthermore, the foregoing materials have good moisture resistance and insulating characteristics.

Furthermore, the filling member 20 may contain filling member for adjustment of viscosity and color. As such filler, chalk, silica, carbon black, calcium carbonate, titanium dioxide, talc, kaolin, mica, and the like are cited as examples. Filling member 20 may also contain antioxidant to reduce deterioration due to oxidation. As such antioxidant, hindered phenols, hindered amines, thioether, and so forth are cited as examples.

Furthermore, the filling member 20 may contain desiccant. The desiccant which may be used are similar to the desiccant which may be contained by the second sealing member 13.

Note that the materials which may be used for the filling member 20 are similar to those at the aforementioned second sealing member 14. Thus, in the present embodiment, because the filling member 20 is arranged at the gap K, it is possible to further reduce entry of moisture/water that would otherwise reach the opening portion 14 from the joint C.

Note that when the second sealing member 13 and the filling member 20 are formed from the same material, the distance S1 may be made larger than the width T of the second sealing member 13 of the photoelectric conversion panel PA. This will permit further reduction in entry of moisture/water.

Furthermore, in the present embodiment, a projection 11a is formed at the conductive leads 11. In such case, the projection 11a comes in contact with the filling member 20 at least other than the tip thereto. This makes it possible to increase the amount of the filling member 20 that can be arranged between the conductive leads 11 and the non-light-receiving surface 2a or moisture barrier plate 15. This makes it possible to further increase the effect whereby the filling member 20 reduces entry of moisture/water. A conductive leads 11 having such projection 11a may, for example, be formed by an embossing operation involving stamping with a die having a non-flat surface profile. Furthermore, the shape of the projection 11a may be elongate and more or less parallel to the width direction of the conductive leads 11, or may be in the shape of randomly formed island-like feature or the like, with height thereof being on the order of 0.1 mm to 3 mm. Note where the conductive leads 11 including such projection 11a also includes an embodiment in which the conductive leads 11 itself is bent in wavelike fashion.

The frame member 16 is arranged on the periphery of the moisture barrier plate 15 so as to enclose conductive leads 11 therewithin. Furthermore, the lid member 17 is arranged at the top face of the frame member 16. As material for the frame member 16 and the lid member 17, resins such as modified PPE (polyphenylene ether), modified PPO (polyphenylene oxide), and the like, are cited as examples. Such resins have good insulating characteristics and ability to withstand outdoor environments over long periods of time.

Stage 18 is arranged on the other principal surface of moisture barrier plate 15 at a location in the vicinity of the central region within terminal box B1. This stage 18 supports the terminal 19 which is electrically connected to conductive leads 11. As material for such stage 18, as was the case with the aforementioned frame member 16 and lid member 17, modified PPE, modified PPO, and other such resins are cited as examples.

The terminal 19 has functionality for guiding electricity from the conductive leads 11 to cable 21. This terminal 19 may, for example, be composed of a strip of copper having a thickness on the order of 0.5 mm to 2 mm, and is secured to the moisture barrier plate 15 by a screw 22a.

The cable 21 has functionality for guiding electricity generated at the photoelectric conversion module M1 to an external load. One end of this cable 21 is secured to the terminal 19 by a screw 22b, and the other end thereof is electrically connected to circuitry or the like at the aforementioned load. As such cable 19, a cable having a multistranded core, of cross-sectional area on the order of 3.5 mm², including on the order of 5 to 20 strands made of copper, the core being covered with polyethylene, vinyl chloride, or the like, may, for example, be employed.

Next, an exemplary method for attaching a terminal box B1 to the photoelectric conversion panel PA will be described. First, after the conductive leads 11 have been guided out of the opening portion 14, the conductive leads 11 are bent in a prescribed direction so as to run alongside the non-light-receiving surface 2a of the photoelectric conversion panel PA. The filling member 20 is then applied between the one principal surface of the moisture barrier plate 15 and the non-light-receiving surface 2a, and the moisture barrier plate 15 is secured to the photoelectric conversion panel PA. At such time, the filling member 20 is applied so as to be respectively arranged at the gap K between the one principal surface of the moisture barrier plate 15 and the conductive leads 11 and between the non-light-receiving surface 2a and the conductive leads 11. The end portion of conductive leads 11 are then routed out therefrom by way of the through-hole 15a so as to reach the other principal surface of the moisture barrier plate 15, and the end portion of conductive leads 11 which have been guided out of the through-hole 15a is secured to the terminal 19 using solder or the like. Note that the moisture barrier plate 15 and the frame member 16 may take the form of components which are secured in advance by means of adhesive or the like, or the moisture barrier plate 15 may be secured first, with the frame member 16 being separately secured to the moisture barrier plate 15 thereafter.

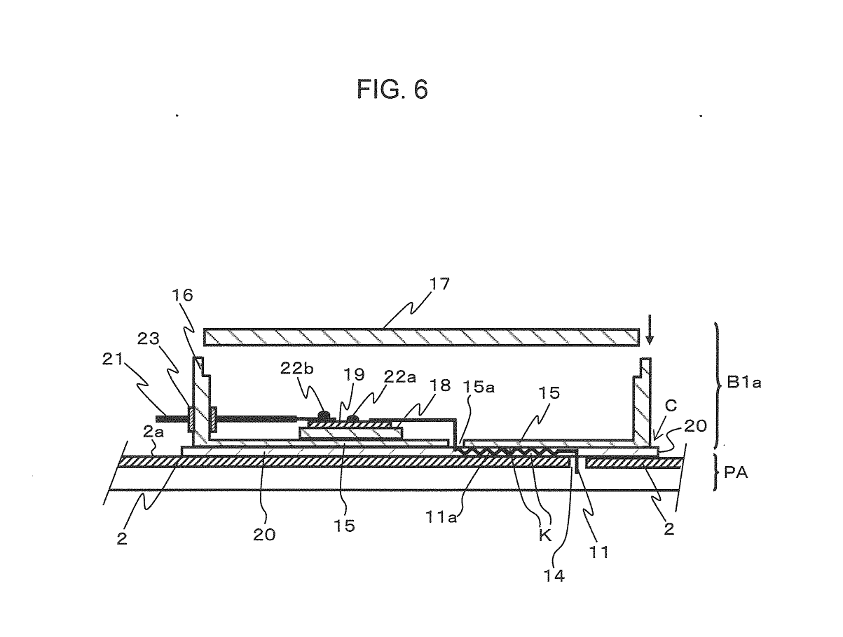

Next, the cable 21 is inserted into the interior of the terminal box B1 from an access hole at a side face of the frame member 16, and the screw 22b is used to secure the conductive portion of the crimped terminal or the like which is attached at the end portion of the cable 21 to terminal 19. At such time, packing 23 to reduce entry of moisture/water may be provided at the access hole of the frame member 16. Lid member 17 is lastly attached and secured thereto by a screw or the like. Prior to attachment of lid member 17, note that the interior of the terminal box B1 may be filled with a potting member such as silicone resin, epoxy resin, or the like. This will permit reduction in occurrence of corrosion at metal members such as the terminal due to moisture/water which has entered thereinto from the exterior. Furthermore, as shown in FIG. 5, when the photoelectric conversion module M1 is such that the moisture barrier plate 15 is arranged within the non-light-receiving surface 2a of the photoelectric conversion panel PA, the opening portion 14 may be located nearer than the through-hole 15a to the central region of the moisture barrier plate 15. As compared, for example, with a situation such as that shown in FIG. 6 in which the opening portion 14 is located nearer than the through-hole 15a to the outer edge of the moisture barrier plate 15 (terminal box B1a), this will make it possible to cause moisture/water to less readily enter the opening portion 14 from the joint C. Moreover, in the embodiment shown in FIG. 5, after the conductive leads 11 have been guided out of the opening portion 14 so as to be directed toward the periphery of the photoelectric conversion panel PA, within the terminal box B1 it is bent toward the central region of the moisture barrier plate 15. As a result, as compared with the embodiment shown in FIG. 6, the embodiment shown in FIG. 5 lends itself more readily to reduction in size of the terminal box.

Variations on the photoelectric conversion panel PA, the conductive leads 11, and the moisture barrier plate 15 will next be described. Although the conductive leads 11 are provided with the projection 11a which comes in contact with the filling member 20 so as to respectively project toward the other principal surface of moisture barrier plate 15 and the non-light-receiving surface 2a of the photoelectric conversion panel PA, it is not limited to this embodiment. That is, the embodiment may be such that, at the gap K between the conductive leads 11 and the moisture barrier plate 15 and the gap K between the conductive leads 11 and the photoelectric conversion panel PA, when such members are brought into compressive contact, the filling member 20 is made to enter and fill the aforementioned gap.

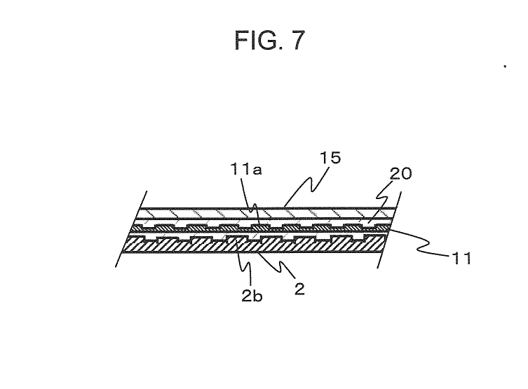

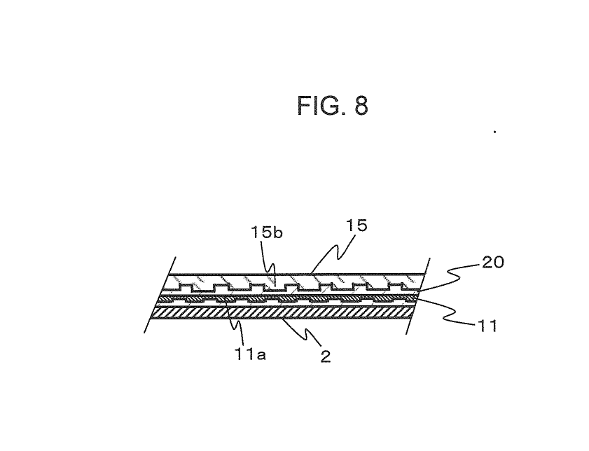

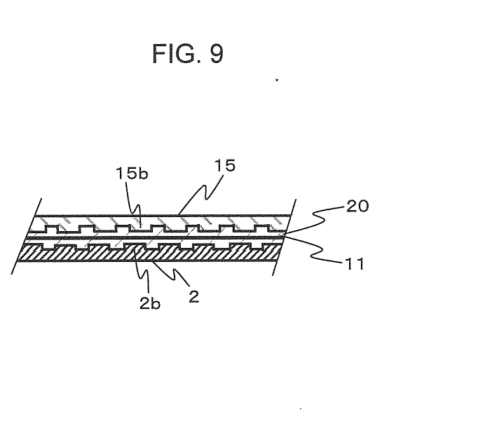

Such an embodiment is shown in FIG. 7, where projection(s) 2b of the non-light-receiving surface 2a of the photoelectric conversion panel PA and the projection(s) 11a of the conductive leads 11 are respectively provided in such fashion as to project toward the one principal surface of the moisture barrier plate 15. Furthermore, another embodiment is shown in FIG. 8, where projection(s) 15b of the one principal surface of the moisture barrier plate 15 and the projection(s) 11a of the conductive leads 11 are respectively provided in such fashion as to project toward the non-light-receiving surface 2a of the photoelectric conversion panel. Furthermore, another embodiment is shown in FIG. 9, where projection(s) 15b of the one principal surface of the moisture barrier plate 15 and projection(s) 2b of the non-light-receiving surface 2a of the photoelectric conversion panel PA are respectively provided in such fashion as to project toward the conductive leads 11.

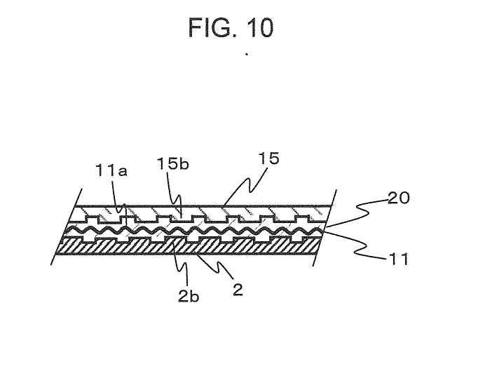

Note that if, as shown in FIG. 10, the aforementioned projections which come in contact with the filling member 20 are respectively formed from the photoelectric conversion panel PA, the conductive leads 11, and the moisture barrier plate 15, it will be possible to increase the area over which the filling member 20 comes in contact with the respective members (the photoelectric conversion panel PA, the conductive leads 11, and the moisture barrier plate 15). Furthermore, as the aforementioned moisture barrier plate 15 and photoelectric conversion panel PA, a member with projections formed by an embossing operation or the like is carried out in advance at moisture barrier plate 15 and first substrate 2. Furthermore, if the projections provided at the respective members including the photoelectric conversion panel PA, the conductive leads 11, and the moisture barrier plate 15 are provided over approximately the entire surfaces at the filling member 20 sides of the respective members, it will be possible to further increase the area over which filling member 20 comes in contact therewith.

### Crystalline-Type Photoelectric Conversion Module

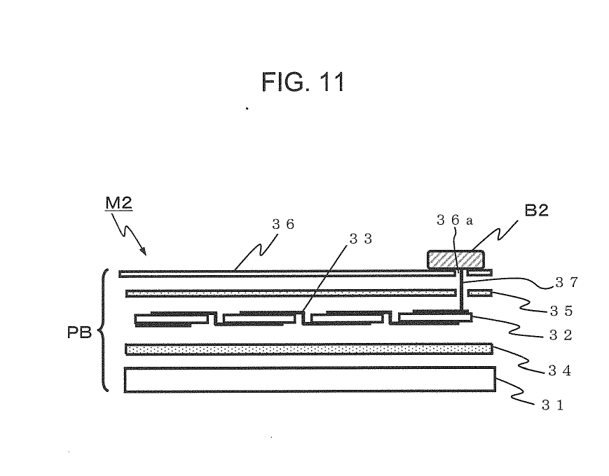

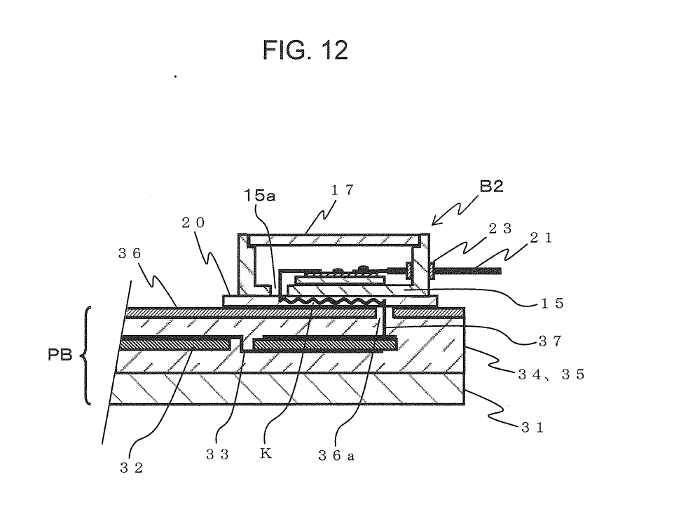

Next, referring to FIGS. 11 through 14, embodiments of crystalline-type photoelectric conversion modules will be described. Photoelectric conversion module M2 includes a photoelectric conversion panel PB and a terminal box B2. As shown in FIG. 11 and FIG. 12, the photoelectric conversion panel PB includes a translucent substrate 31, plurality of photoelectric converters 32, and conductive connectors 33 which electrically interconnect mutually neighboring photoelectric converters 32. The photoelectric conversion panel PB further includes a light-receiving-side sealing member 34 and a non-light-receiving-side sealing member 35 which seal the photoelectric converters 32 and the conductive connectors 33, a back sheet 36, and a conductive lead 37. Note that the terminal box B2 is attached to the back sheet 36 which corresponds to the non-light-receiving surface of photoelectric conversion module M2.

As translucent substrate 31, substrate comprising glass, polycarbonate resin, or the like may be employed. As the aforementioned glass, super white crown glass, tempered glass, heart-strengthed glass, heat-strengthened glass, light reflective glass, or the like may be employed. When the aforementioned glass is employed, thickness of the translucent substrate 31 may be on the order of 3 mm to 5 mm. On the other hand, when polycarbonate resin or other such synthetic resin is employed, thickness of the translucent substrate 31 may be on the order of 5 mm.

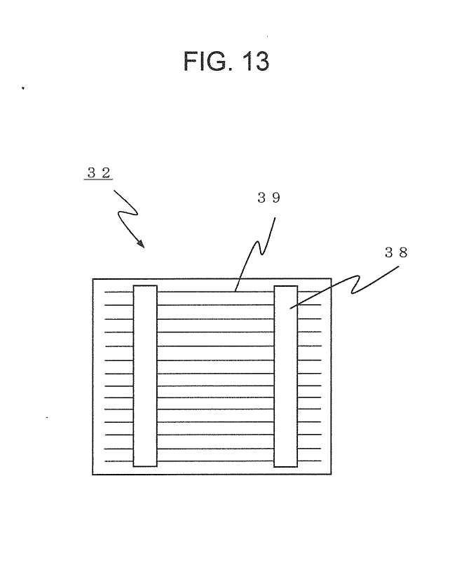

As shown in FIG. 13, the photoelectric converter 32 may be planar in shape, being formed, for example, from monocrystalline silicon, polycrystalline silicon, or the like which is such that thickness thereof is on the order of 0.2 mm to 0.4 mm, and size thereof is on the order of 150 mm to 160 mm, square. Formed at the interior of this photoelectric converter 32 is a PN junction (not shown) at which a P layer containing an abundance of P-type dopant such as boron and an N-type layer containing an abundance of N-type dopant such as phosphorous come in mutual contact. Furthermore, busbar electrodes 38 and finger electrodes 39 are provided at photoelectric converter 32. The busbar electrodes 38 and the finger electrodes 39 is formed, for example, by screen printing of electrically conductive paste that contains silver or the like. The finger electrode 39, which has functionality for gathering carriers, is formed so as be on the order of 0.1 mm to 0.2 mm in width. Furthermore, a multiplicity of finger electrodes 39 is formed at intervals of approximately 2 mm to 4 mm in such fashion as to be parallel to one side of the photoelectric converter 32. Furthermore, on the order of two to three busbar electrodes 38, which have functionality for collecting carriers gathered by the finger electrodes 39, are formed so as to intersect the finger electrodes 39 in perpendicular fashion. Furthermore, because the busbar electrodes 38 are electrically connected to the conductive connector 33, the busbar electrodes 38 are formed such that width thereof is on the order of 1 mm to 3 mm. Note that approximately the entire surface of the busbar electrode 38 may be coated with solder for protection thereof and so as to facilitate attachment of conductive connector 33 thereto. Note that busbar electrodes 38 are also formed in similar fashion at the non-light-receiving side of the photoelectric converter 32.

The conductive connector(s) 33 have functionality for causing busbar electrodes 38 of mutually neighboring photoelectric converters 32 to be electrically interconnected and for causing a plurality of photoelectric converters 32 to be connected in series. More specifically, the conductive connector 33 causes a busbar electrode 38 formed on a light-receiving surface of one photoelectric converter 32 to be electrically connected to a busbar electrode 38 formed on a non-light-receiving surface of another photoelectric converter 32. The conductive connector 33 is, for example, metal foil such as copper, aluminum, or the like that has been coated with solder of thickness on the order of 20 μm to 70 μm. To prevent the conductive connector 33 itself from creating shadow at the light-receiving surface of the photoelectric converter 32 when soldering is being carried out, width of this conductive connector 33 may be made the same as the busbar electrode 38 of the photoelectric converter 32, or may be made smaller than the width of the busbar electrode 38. The conductive connector 33 may have enough length for permitting the busbar electrodes 38 of adjacent photoelectric converters 32 to be electrically interconnected. At such time, conductive connector 33 is connected so as to more or less completely overlap the busbar electrode 38 of the photoelectric converter 32. This will make it possible to lower resistance of photoelectric converter 32. For example, when a photoelectric converter 32 having a polycrystalline silicon substrate which is on the order of 150 mm, square, is employed, width of conductive connector 33 is on the order of 1 mm to 3 mm, and length thereof is on the order of 250 mm to 300 mm.

As the light-receiving-side sealing member 34 and the non-light-receiving-side sealing member 35, EVA or polyvinyl butyral (PVB) that has been molded into sheets on the order of 0.4 mm to 1 mm in thickness using T die and an extruder may be employed. A laminator may be used to apply heat and pressure under reduced pressure to cause these to soften and fuse with other members so as to form an integral structure. Note that the non-light-receiving-side sealing member 35 need not be transparent, it being possible to cause titanium oxide or pigment or the like to be present therein so as to make it colored with white color or the like as to match the surrounding environment in which the photoelectric conversion module is installed.

The back sheet 36 protects the photoelectric converter 32 and so forth from the exterior and also reduces entry of moisture/water and so forth thereinto from the exterior. As such back sheet 36, weather-resistant fluorinated resin sheeting which sandwiches aluminum foil therebetween, polyethylene terephthalate (PET) sheeting on which alumina or silica has been vapor-deposited, and/or the like may, for example, be employed. In addition, the back sheet 36 may be provided with an opening portion 36a.

The conductive lead 37 is electrically connected to the photoelectric converter 32 within the photoelectric conversion panel PB, being guided to the terminal box B2 from the opening portion 36a of the back sheet 36 as shown in FIG. 11 and FIG. 12. As such conductive lead 37, similar materials as were mentioned with respect to the aforementioned conductive lead 11 of the photoelectric conversion module M1 may also be employed here. Note that the terminal box B2 provided at the photoelectric conversion module M2 is similar in constitution to the terminal box B1 provided at the photoelectric conversion module M1.

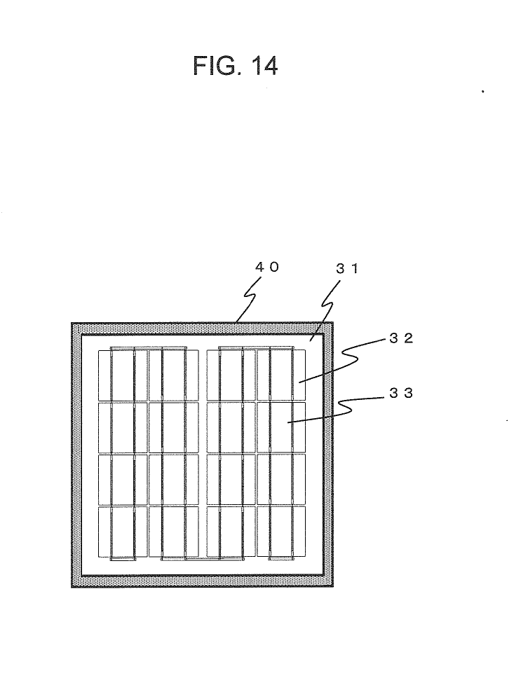

An exemplary method of manufacturing photoelectric conversion module M2 will next be described. As shown in FIG. 14, the photoelectric converters 32 are connected in series by the conductive connector(s) 33 and are arranged in matrix-like fashion. The conductive leads 37 may then be connected those photoelectric converters 32 which are at either end of the photoelectric converters 32 connected in series.

The translucent substrate 31, the light-receiving-side sealing member 34, the photoelectric converter 32 connected by the conductive connector 33, the non-light-receiving-side sealing member 35, and the back sheet 36 are then sequentially placed one atop the other to form a laminated body. At such time, one end portion of conductive lead 37 is routed out therefrom to the back side of the back sheet 36 from the opening portion 36a of the back sheet 36 and the through-hole formed in advance at the non-light-receiving-side sealing member 35. The foregoing laminated body is then arranged inside a laminator and then heated while being subjected to compressive load under reduced pressure so as to be made into an integral structure. During this laminating operation, the light-receiving-side sealing member 34 and the non-light-receiving-side sealing member 35 are held for on the order of 15 min to 60 min at a temperature that will cause softening and crosslinking of (e.g., on the order of 120° C. to 160° C.) so as to cause the foregoing laminated body to become an integral structure.

The end portion of the conductive lead 37 which has been routed out therefrom to the back side of the back sheet 36 is then guided to the interior of terminal box B2. A similar method as employed at the photoelectric conversion module M1 may lastly be employed to attach the terminal box B2 to the top surface of the back sheet 36 (the non-light-receiving surface of photoelectric conversion panel PB). At the photoelectric conversion module M2, note as shown in FIG. 14 that the frame portion 40 may be attached at the periphery of the photoelectric conversion panel PB so as to reduce damage to the photoelectric conversion panel PB.

Similar to the photoelectric conversion module M1, such photoelectric conversion module M2 will make it possible to reduce entry of moisture/water thereinto from the exterior and to improve reliability.

### Variations

Another embodiment of a photoelectric conversion module according to the present invention will next be described with reference to FIG. 9. The photoelectric conversion module M3 shown in FIG. 9 differs from the aforementioned photoelectric conversion module M1 with respect to the structure of the terminal box. More specifically, unlike the terminal box B1, a terminal box B3 provided at the photoelectric conversion module M3 is such that the moisture barrier plate 15 is provided in the form of a member separate from the bottom member of the terminal box. That is, at the terminal box B1, the bottom member of the terminal box B1 serves as the moisture barrier plate 15.

At the terminal box B3, because the moisture barrier plate 15 is a member separate from the bottom member of terminal box B3, there is increased freedom with respect to selection of the moisture barrier plate 15. That is, the materials which are employed at the moisture barrier plate 15 of terminal box B3 are not limited to materials such as those which can be used at the bottom member of terminal box B1. For this reason, glass or metal which has better ability to withstand moisture/water and endurance are more readily employed at the moisture barrier plate 15 of terminal box B3 as compared with the resin materials which are more readily employed at the terminal box B1. More specifically, when the moisture barrier plate 15 is to be formed from glass, soda-lime glass having a thickness on the order of 0.3 mm to 1.0 mm may, for example, be employed. Furthermore, aluminum, stainless steel, or the like may be employed when the moisture barrier plate 15 is to be formed from metal. At such time, the foregoing metal plate may be coated with insulating material such as resin, glass, or the like. This will make it possible for the moisture barrier plate 15 to have insulating characteristics. Such the moisture barrier plate 15 may, for example, be fitted in the bottom member of the terminal box B3. Alternatively, epoxy-type adhesive or the like may be used to cause the moisture barrier plate 15 to adhere to the bottom member of terminal box B3.

Furthermore, the terminal box B3 also differs from the terminal box B1 with respect to the potting material with which the interior of the terminal box is filled. More specifically, the terminal box B3 differs from the terminal box B1 in that the former employs two types of potting material (first potting material 41 and second potting material 42).

The first potting material 41 is arranged so as to cover the conductive leads 11, the stage(s) 18, the terminal(s) 19, and so forth. As such first potting material 41, material having good endurance may be employed. Butyl rubber is cited as an example of such a material.

The second potting material 42 is arranged on the first potting material 41. As such second potting material 42, material having good heat resistance may be employed. Silicone resin is cited as an example of such a material. Silicone resin, which does not readily change shape even at temperatures of on the order of 50° C. to 100° C., has good heat resistance.

Thus, the terminal box B3, which employs two types of potting material, will make it possible to reduce flow of the first potting material 41 even in an environment of high temperature. As a result, reliability of the photoelectric conversion module M3 under high-temperature conditions will be further improved.

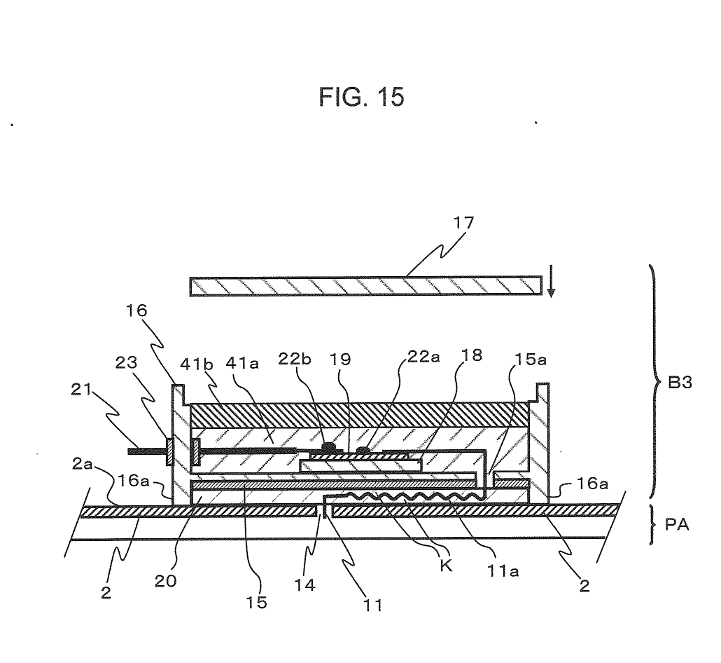

Furthermore, as shown in FIG. 15, the terminal box B3 may be such that portions of the frame member 16 are provided with foot regions 16a. Providing such foot regions 16a will make it possible to further increase thickness of the filling member 20 at location(s) between the one principal surface of the moisture barrier plate 15 and the non-light-receiving surface 2a of the photoelectric conversion panel PA. This will make it possible to further reduce entry of moisture/water. Height of such foot regions 16a may, for example, be on the order of 1 mm to 5 mm. Furthermore, such foot regions 16a may, for example, be formed by injection molding or the like so as to be integral with the frame member 16.

The present invention is not limited to the foregoing embodiments but admits of a great many revisions and variations within the scope of the present invention. For example, at a thin-film-type photoelectric conversion module, amorphous silicon layers may be used instead of semiconductor layer(s) and buffer layer(s). Furthermore, at a crystalline-type photoelectric conversion module, microcrystalline silicon may be used instead of crystalline silicon.

### EXPLANATION OF REFERENCE NUMERALS

M1-M3: Photoelectric conversion module
B1-B3, B1a: Terminal box
PA, PB: Photoelectric conversion panel
1, 32: Photoelectric converter
2: First substrate
2a: Non-light-receiving surface
2b: Projection(s)
3: Back electrode
4: Semiconductor layer
5: Buffer layer
6: Translucent electrically conductive layer
7: Current-collecting electrode
8: Output-extracting portion
9: Second substrate
11, 37: Conductive lead
11a: Projection(s)
12: First sealing member
13: Second sealing member
14: Opening portion
15: Moisture barrier plate
15a: Through-hole
15b: Projection(s)
16: Frame
16a: Foot region
17: Lid member
18: Stage
19: Terminal
20: Filling member
21: Cable
22a, 22b: Screw
23: Packing
31: Translucent substrate
33: Conductive connector
34: Light-receiving-side sealing member
35: Non-light-receiving-side sealing member
36: Back sheet
38: Bus bar electrode
39: Finger electrode
40: Frame member
41: First potting material
42: Second potting material

1. A photoelectric conversion module comprising:
a photoelectric conversion panel comprising:
a first surface;
a second surface opposite to the first surface;
a photoelectric converter located between the first surface and the second surface;
a conductive lead electrically connected to the photoelectric converter; and
an opening which is open at the first surface and through which the conductive lead is guided to the exterior; and
a moisture barrier plate comprising:
a first principal surface;
a second principal surface opposite to the first principal surface; and
a through-hole extending from the first principal surface to the second principal surface,
wherein the moisture barrier plate is arranged at the second surface so as to cause the opening to be covered by the one principal surface;
wherein the moisture barrier plate is arranged such that, as seen in plan view, the through-hole does not overlap the opening;
wherein the conductive lead is arranged so as to create a gap at a location between the first surface and the first principal surface, and is guided to the exterior from the through-hole; and wherein filling member is arranged in the gap.

2. The photoelectric conversion module according to claim 1
wherein the moisture barrier plate is arranged within the second surface in a plan view; and
the opening is located nearer than the through-hole to a central region of the moisture barrier plate.

3. The photoelectric conversion module according to claim 1, wherein a projection is located at the conductive lead, the projection projecting toward the first principal surface and the second surface and being in contact with the filling member.

4. The photoelectric conversion module according to claim 1, wherein projections are located at the first principal surface and at the conductive lead, the projection projecting toward the second surface and being in contact with the filling member.

5. The photoelectric conversion module according to claim 1, wherein projections are located at the second surface and at the conductive lead, the projection projecting toward the first principal surface and being in contact with the filling member.

6. The photoelectric conversion module according to claim 1, wherein projections are located at the first principal surface and at the second surface, the projection projecting toward the conductive lead.

7. The photoelectric conversion module according to claim 1, wherein the moisture barrier plate has insulating characteristics.

8. The photoelectric conversion module according to claim 1, wherein the filling member comprises desiccant.

9. The photoelectric conversion module according to claim 1, further comprising a frame body located on the other principal surface and enclosing the conductive lead therewithin.

10. A photoelectric conversion module comprising:
a photoelectric conversion panel comprising:
a surface plate comprising a through-hole;
a photoelectric converter therein; and
a lead comprising a first end portion electrically coupled to the photoelectric converter, a second end portion located outside of the photoelectric conversion panel, and a line portion between the first and second end portions; and
a moisture barrier plate comprising:
a body that covers the through-hole of the surface plate; and
a hole that penetrates the body and that is away from the through-hole,
a filling member between the surface plate of the photoelectric conversion panel and the moisture barrier plate,
wherein the line portion of the lead comes outside of the photoelectric conversion panel from inside through the through-hole, and travels through a part of the filling member.
